(19) United States
(12) Patent Application Publication
(10) Pub. No.: US 2014/0192603 A1
(43) Pub. Date: Jul. 10, 2014

(54) DIFFERENTIAL SENSE AMPLIFIER FOR SOLID-STATE MEMORIES

(71) Applicant: LSI CORPORATION, Milpitas, CA (US)

(72) Inventor: Sahilpreet Singh, Bangalore (IN)

(73) Assignee: LSI CORPORATION, Milpitas, CA (US)

(21) Appl. No.: 13/736,528

(22) Filed: Jan. 8, 2013

(51) Int. Cl. G11C 7/06; G11C 7/12

(52) U.S. Cl. CPC G11C 7/06; G11C 7/12
USPC 365/203; 365/207

(57) ABSTRACT

Described embodiments provide a memory having at least one sense amplifier with inputs coupled to at least one pair of bit lines. One of the pair of bit lines is precharged to a power supply voltage and a second one of the pair is precharged to ground. A first switch DC-couples the first one of the pair of bit lines to a first input of a cross-coupled amplifier. A first capacitor AC-couples the second one of the pair of bit lines to a second input of the cross-coupled amplifier. Then a memory cell coupled between the first and second one of the pair of bit lines is enabled. A switch then decouples the first input from the bit line, a second capacitor is used to inject a charge of current into the first input of the cross-coupled amplifier, and then the cross-coupled amplifier is enabled.

### BACKGROUND OF THE INVENTION

A typical solid-state memory device has multiple memory cells coupled to bit lines that facilitate the extraction of data stored in memory cells, the extracted data to be presented at an output of the device. When data is to be read from a cell, the cell is activated and a transistor in the cell (generally referred to as an access transistor) will or will not change a pre-established voltage on the bit line depending on the data stored in the active cell. Because transistors in the memory cells are typically very small and thus are weak, and generally each bit-line is coupled to hundreds of other (inactive) cells resulting in each bit-line having significant capacitive loading, the amount of change in bit-line voltage during a defined time period is relatively small. To determine what data value, the active cell is storing, each bit-line has attached thereto a sense amplifier that amplifies any change in the bit-line voltage and “slices” the amplified voltage change to produce at an output of the sense amplifier a binary one or zero. The output of the sense amplifier is then coupled to the output of the memory for use in the apparatus using the memory device, e.g., a computer.

Bit-lines are of two types: differential and single-ended. Differential bit-lines are less susceptible to induced noise than single-ended hit-lines but a memory having differential bit-lines requires twice the number of bit-line conductors compared to a memory with single-ended bit-lines and a concomitant increase in memory complexity and area. However, a memory with differential bit lines might have the fastest memory access time (used here as the time required for the memory to present data at its output measured from when an address is first applied to the memory and the memory enabled) and is normally used where a memory cell has differential outputs, e.g., static random access memory (SRAM). For those memory devices having non-differential output memory cells, single-ended bit-lines are used, such as in a read-only memory (ROM), electrically-programmable memory (e.g., EEPROM, FLASH, etc.), or a dynamic random access memory (DRAM). However, some memory designs that would otherwise use single-ended bit-lines, it might be desirable to find a way to use differential bit-lines so that the memory can operate faster than a single-ended design.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Described embodiments provide a memory having at least one sense amplifier. The at least one sense amplifier has a cross-coupled gain stage with first and second amplifier nodes, first and second switches, and first and second capacitors. The first switch, in response to a control signal, selectively couples the first amplifier node to a first input of the sense amplifier. The second switch, in response to the control signal, selectively couples a first internal node to a second input of the sense amplifier. The first capacitor is coupled between the first internal node and the second amplifier node, and the second capacitor is coupled between the first amplifier input and a second internal node.

### BRIEF DESCRIPTION OF THE DRAWINGS

Other embodiments of the present invention will become more fully apparent from the following detailed description, the appended claims, and the accompanying drawings in which like reference numerals identify similar or identical elements.

FIG. 1 is a simplified block diagram illustrating an exemplary memory according to an embodiment of the invention;

FIG. 2 is a simplified schematic diagram of a sense amplifier according to an embodiment of the invention;

FIG. 3 is a timing diagram of operation of the memory of FIG. 1 and the sense amplifier of FIG. 2 when the bit lines discharge;

FIG. 4 is a timing diagram of operation of the memory of FIG. 1 and the sense amplifier of FIG. 2 when the bit lines are not discharged; and

FIGS. 5 and 6 are simplified schematic diagrams of alternative memory cells.

### DETAILED DESCRIPTION

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation”.

It should be understood that the steps of the exemplary methods set forth herein are not necessarily required to be performed in the order described, and the order of the steps of such methods should be understood to be merely exemplary. Likewise, additional steps might be included in such methods, and certain steps might be omitted or combined, in methods consistent with various embodiments of the present invention.

Also for purposes of this description, the terms “couple”, “coupling”, “coupled”, “connect”, “connecting”, or “connected” refer to any manner known in the art or later developed in which energy is allowed to be transferred between two or more elements, and the interposition of one or more additional elements is contemplated, although not required. Conversely, the terms “directly coupled”, “directly connected”, etc., imply the absence of such additional elements. Signals and corresponding nodes or ports might be referred to by the same name and are interchangeable for purposes here. The term “or” should be interpreted as inclusive unless stated otherwise. Further, elements in a figure having subscripted reference numbers, (e.g., 100₁, 100₂, . . . 100_{K} might be collectively referred to herein using the reference number 100.

The present invention will be described herein in the context of illustrative embodiments of a sense amplifier adapted for use in a solid-state memory, such as a read-only, a dynamic random access memory, or the like. It is to be appreciated, however, that the invention is not limited to the specific apparatus and methods illustratively shown and described herein.

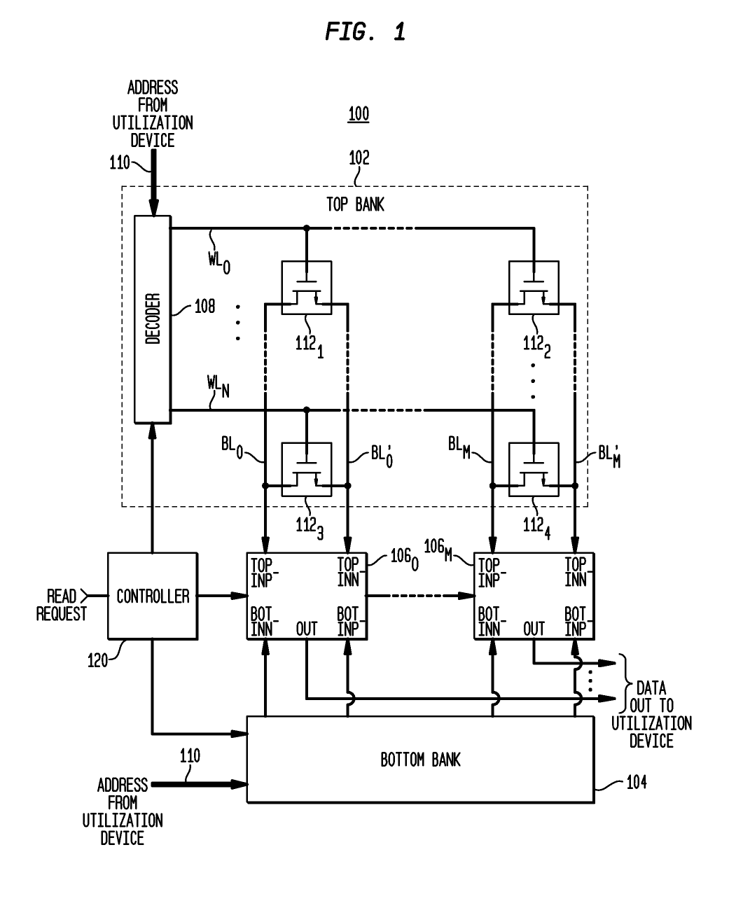

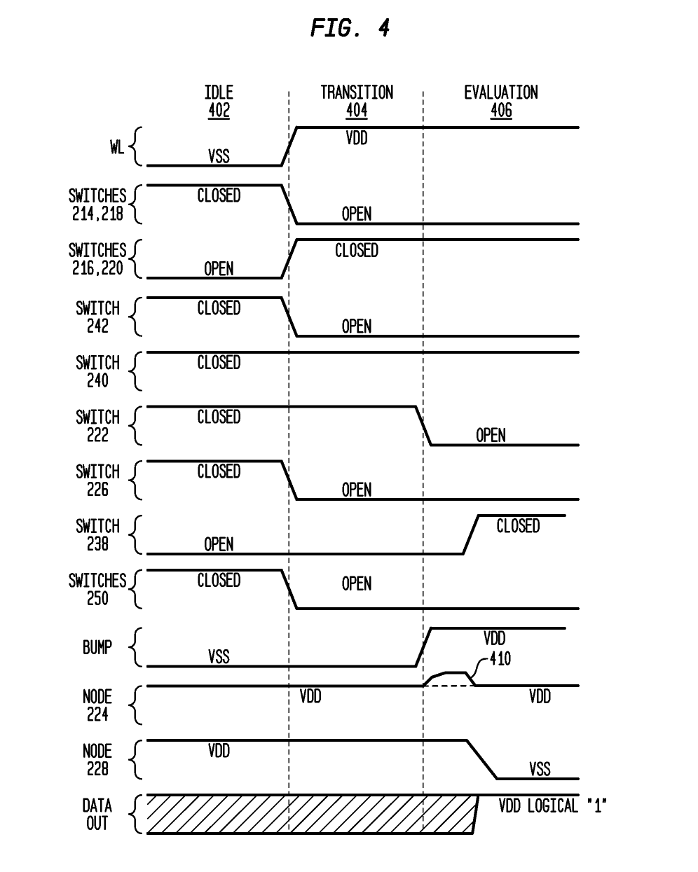

FIG. 1 is a generalized block diagram of an exemplary solid-state memory 100 integrated in a single substrate, e.g., a silicon substrate, either stand-alone or includes other components such as a processor. For purposes of this description, this exemplary embodiment is as a read-only memory (ROM) programmed at manufacture using lithographic techniques (selective metallization of the memory cells 112 using one or more masks) or laser-programmed fuses (not shown). However, as illustrated in connection with FIG. 4, it is understood that in alternative embodiments the memory 100 can be a field-programmable ROM (using programmable fuses), dynamic random access memory (DRAM), or an electrically programmable memory cell (EPROM, EEPROM, FLASH, etc.) based on the memory cell type and the presence of the necessary support circuitry e.g., write drivers, programming voltage generators, write data lines, etc., not shown).

The memory 100 is organized into two banks, a top bank 102 and a substantially identical bottom bank 104. These banks share common sense amplifiers 106 although only one bank at a time is active. For purposes here, only the top bank 102 is described but the features and operation of the bottom bank 104 is the same.

In the top bank 102, a conventional address decoder 108 receives a multi-bit address via address bus 110 from a utilization device such as a computer or the like. The address decoder 108 enables one of several word lines WL₀-WL_{N} (N is an integer ≧1) in response to the address. In this example, an enabled word line has a voltage substantially equal to V_{DD} (the power supply voltage) whereas the remaining word lines have a voltage of substantially zero volts. These voltages are sufficient to turn on and turn off an access transistor in each of the memory cells 112, described below. It is understood that the decoder 108 may assert other voltages on the word lines.

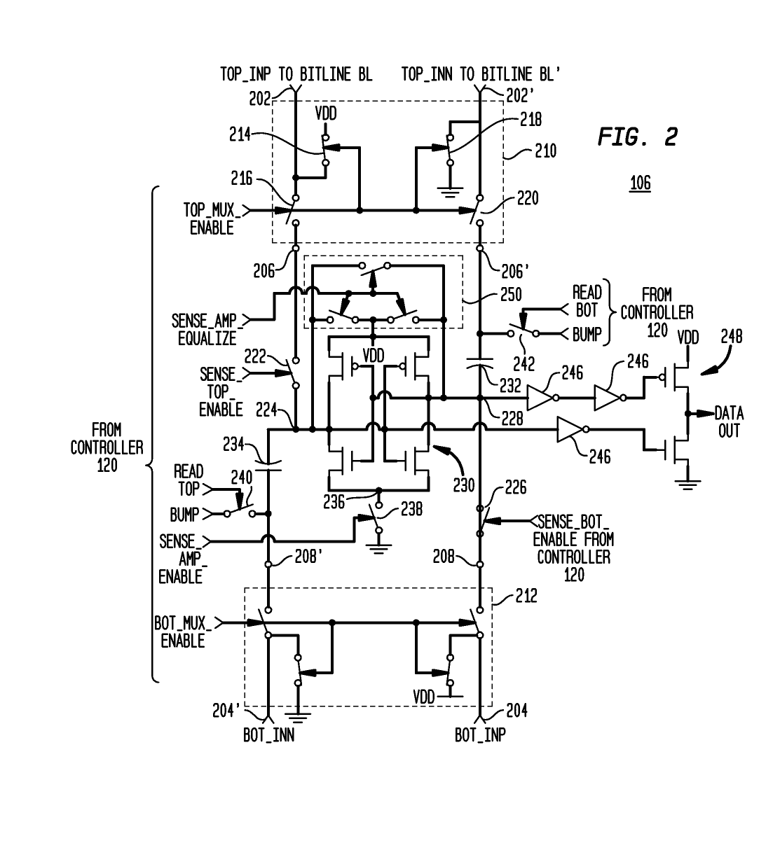

Each of the memory cells 112 have an input coupled to a corresponding word line and an output coupled to corresponding bit line pairs BL₀, BL₀′-BL_{M}, BL_{M}′ where M is an integer ≧0. The bit lines couple the outputs of the memory cells coupled thereto to an input TOP_INP, TOP_INN of a corresponding sense amplifier 106₀-106_{M}. As will be explained in more detail below in connection with FIG. 2 the sense amplifiers amplify relatively small signals on the corresponding bit lines to determine the logic value of data stored in the memory cells, e.g., a logical one (1) or zero (0). Logic-level signals (having a voltage of approximately V_{DD} for a logical “1” and ground or approximately zero volts for a logical “0” in this embodiment but in an alternative embodiment, the voltages are reversed) on the output OUT of each sense amplifier are coupled to the utilization device to form an output of one or more bits. Alternatively, one or more multiplexers (not shown) responsive to additional address bits from the utilization device might be used to select a subset of the data bits from the sense amplifiers for coupling to the utilization device.

In this embodiment, each of the memory cells 112 comprises an access transistor (not numbered) having a gate or control terminal coupled to the corresponding word line (WL) and a drain terminal (an output terminal) coupled to a first (true) corresponding bit line (BL). The data value stored in a given memory cell is established by whether or not the source terminal (also an output terminal) of the access transistor is coupled to a second (complementary) bit line (BL′) or is not so connected. For example, the source terminal of the access transistor in memory cell 112₂ is coupled to the bit line BL_{M}′ and thus stores a logical 0, whereas the access transistor in cell 112₁ is not connected to bit line BL₀′ and that cell stores a logical 1 although in an alternative embodiment the logic values are reversed. In an alternative embodiment, in each memory cell the source terminal is coupled to the complementary bit line and the drain terminals are either coupled or not coupled to the corresponding true bit line depending on the data value to be stored in the memory cell.

Data on the bit line pairs BL, BL′ is described herein as “complementary” even though the voltages on the bit lines do not change significantly when a memory cell does not conduct (a non-discharge condition).

Operation of the memory 100 is under the control of controller 120. The controller 120 is a conventional state machine or logic block configured to perform a read operation (and write operations if the memory is suitably configured) in response to a read request. The controller receives a subset (not shown) of the memory address bits from bus 110 so as to configure the sense amplifiers 106 to read data from the desired memory bank or, when the sense amplifiers are coupled to multiple bit line pairs in one bank, read data from the desired pair of the multiple bit line pairs.

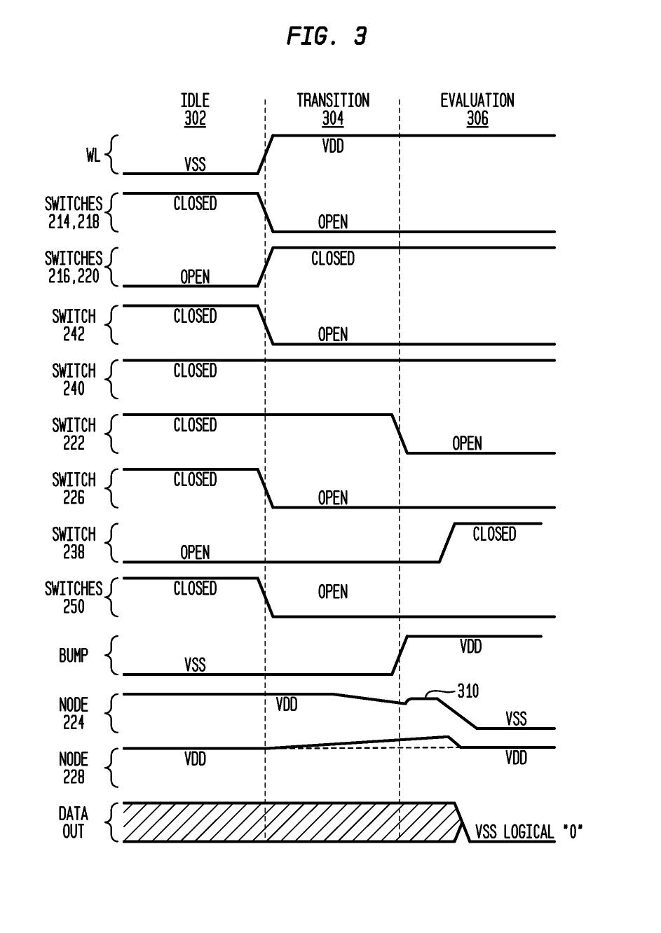

In response to the controller 120 and prior to reading data out of the memory 100, the bit line pairs BL₀, BL₀′-BL_{N}′ are precharged/discharged by the sense amplifiers 106. As will be explained in more detail in connection with FIG. 3, precharge circuitry in the sense amplifiers charge the bit lines BL by applying, in this example, a voltage of approximately V_{DD} to the bit lines by coupling the bit lines to the power supply node V_{DD} before the address decoder 102 is enabled. Similarly, precharge circuitry in the sense amplifiers 106 “precharge” (in effect, discharge) the complementary bit lines BL′ by applying, in this example, a voltage of approximately ground potential (V_{SS} or zero volts) to the bit lines by coupling the bit lines to ground before the address decoder 102 is enabled. (As used in this description, “precharge” refers to the establishment of a known voltage on a node that might require the addition or removal of charge from that node.) Then, when the controller 112 receives a read request, the precharge circuitry is disabled, the sense amplifiers enabled, and address decoder 108 is enabled to cause one of the word lines, e.g., WL₀ to go high. Assuming that word line WL₀ is the enabled word line, the bit lines BL_{M}, BL_{M}′ are coupled together by the enabled access transistor in the cell 112, resulting in the voltage on bit line BL_{M} at least partially discharged toward ground and the voltage on bit line BL_{M}′ at least partially charged toward V_{DD}, whereas the bit line BL₀ will not be discharged and BL₀′ charged because the source terminal of the access transistor in cell 112₁ is not connected to the bit line BL₀′. The sense amplifiers are enabled by the controller 120 and sense amplifier 106_{M} detects the discharging of the hit line BL_{M} and the charging of bit line BL_{M}′ by cell 112₂ and, as a result, outputs a logical “0”. Correspondingly, the sense amplifier 106₀ does not detect a discharge of the bit line BL₀ and charge of the bit line BL₀′, and as a result the sense amplifier outputs a logical “1”. Because of the relatively large parasitic capacitance of the bit lines, the rate of change in the bit line voltages might be somewhat slow, so that the sense amplifiers are configured to detect a small change in bit line voltage and reliably determine whether the change in voltage is due to an enabled memory cell or just noise or leakage current.

FIG. 2 illustrates an exemplary embodiment of one of the sense amplifiers 106 shown in FIG. 1. Inputs 202 (TOP_INP), 202′ (TOP_INN) to the sense amplifier is coupled to corresponding pairs of bit lines BL, BL′ in the top bank 102 in memory 100 (FIG. 1). Similarly, inputs 204 (BOT_INP), 204′ (BOT_INN) couple to corresponding pairs of bit lines in the bottom bank 104 of memory 100. It is understood that in an alternative embodiment, one of the banks 102, 104 might not be present or the sense amplifiers 106 are not shared between the two banks, removing the need for one of the inputs 202, 202′ or 204, 204′ and the corresponding circuitry as will be apparent from the discussion herein.

Each of the inputs 202, 202′ and 204, 204′ are coupled to corresponding nodes 206, 206′ and 208, 208′ by multiplexers 210 and 212, respectively. These nodes can be connected to other multiplexers (not shown) to facilitate sharing of the sense amplifier 106 with additional bit line pairs in the respective banks 102, 104 to reduce the total number of sense amplifiers in the memory 100 as required. Selection of which multiplexer is enabled is determined by the address applied to the controller 120.

The multiplexers 210, 212 each have two pairs of switches 214, 216 and 218, 220. Referring to just multiplexer 210 (multiplexer 212 is substantially the same as multiplexer 210 in this embodiment), the first pair of switches 214, 216, controlled by a common control signal TOP_MUX_ENABLE, either couple the bit line connected to input 202 to a power supply node V_{DD} or to the node 206. Similarly, the second pair of switches 218, 220, controlled by the common control signal that controls switches 214 and 216, either couple the bit line connected to input 202′ to ground or to the node 206′. Switches 214, 218 are closed to precharge the bit lines and switches 216, 220 are closed when data is being read out of the top bank 102.

In one embodiment, the switches 214, 216 are p-channel metal-oxide-semiconductor (PMOS) transistors and switches 218, 220 are n-channel metal-oxide-semiconductor (NMOS) transistors.

In response to control signal SENSE_TOP_ENABLE, switch 222 couples node 206 to node 224 when data is being read from the top bank 102 and switch 226, in response to control signal SENSE_BOT_ENABLE, couples node 208 to node 228 when data is being read from the bottom bank. As will be explained in more detail in connection with FIG. 3, these switches open to reduce the capacitive loading of the multiplexers connected to node 206 and 208 from slowing down operation of the cross-coupled amplifier 230 as it resolves value of the data being read.

Capacitor 232 AC-couples the node 206′ to node 228 and capacitor 234 AC-couples node 208′ to node 224. These capacitors allow the bit lines in each pair of bit lines to have a significant voltage difference (e.g., bit line BL at V_{DD} and BL′ at ground) during precharge or idle state of the memory without upsetting operation of the cross-coupled amplifier during the evaluation state or phase of reading data from the memory as will be explained in more detail in connection with FIG. 3.

To precharge the capacitors 232 and 234 prior to reading data from the memory cells 112 (FIG. 1) and to equalize cross-coupled amplifier 230, nodes 224 and 228 are coupled to and forced to have substantially the same voltage by switch group 250 when signal SENSE_AMP_EQUALIZE is asserted. The switches in the switch group 250 are typically implemented with PMOS transistors. As will be explained in more detail in connection with FIGS. 3 and 4, the switches in switch group 250 are closed during idle periods and are open when data is being read from the memory cells 112.

Each of the capacitors 232, 234 can be implemented using MOS transistors or metal-insulator-metal (MIM) capacitors. To implement the capacitors using MOS transistors, the gate terminal as one terminal of the capacitor and the source and drain terminals connected together as the other terminal of the capacitor.

Cross-coupled amplifier 230 has two conventional inverters (not numbered) with the input of each inverter connected to the output of the other inverter. Both inverters have an NMOS transistor and a PMOS transistor serially coupled between the power supply node V_{DD} and a common node 238. A switch 238, typically an NMOS transistor, couples the node 236 to ground when enabled by control signal SENSE_AMP_ENABLE.

As will be explained in more detail in connection with FIGS. 3 and 4, switches 240, 242 couple a signal BUMP to the nodes 224, 228 when reading data from the top bank 102 or bottom bank 104, respectively. The BUMP signal from the controller 120 is used to inject a small amount of charge into node 224 when reading from the top bank 102 or into node 228 when reading from the bottom bank 104 so that the cross-coupled amplifier 230, by virtue of positive feedback resulting from the cross-coupling, stabilizes into the correct, steady state when no change in the bit line voltage occurs. The amount of charge injected and the resulting “bump” in voltage on the node is not so large as to have a significant effect on the cross-coupled amplifier when there is a change in the bit line voltages. The amount of charge is determined by the change in voltage of the signal BUMP (typically going from substantially ground to approximately V_{DD}) and the capacitance of capacitors 232, 234. Because current flows in either direction through the switches 240, 242, those switches are typically transmission gates having paralleled PMOS and NMOS transistors. If only one bank is implemented, one of the switches 240, 242 may be removed. For example, if the bottom bank 104 is not implemented, then the switch 240 is replaced so that the BUMP signal is coupled directly to the capacitor 234, and switch 226 and multiplexer 212 are not implemented.

The signal BUMP is substantially equal to ground potential during the idle state of the memory 100 so that the switches 240, 242 assure that the capacitors 234, 232, respectively, are discharged. However, if the top bank 102 is to be read, then switch 242 opens so that any change in voltage on the bit line connected to terminal 202′ is conveyed to the cross-coupled amplifier 230. Similarly, if the bottom bank 104 is to be read, then switch 240 opens so that any change in voltage on the bit line connected to terminal 204′ is conveyed to the cross-coupled amplifier 230.

The data value of the enabled memory cell is determined by the cross-coupled amplifier 230 is buffered by inverters 246 coupled to nodes 224, 228. The inverters in turn drive output stage 248 of serially connected transistors (not numbered) that produces the output of the sense amplifier, DATA OUT. It is understood that the output implementation shown here is exemplary and that other implementations may be used instead of that shown here.

FIGS. 3 and 4 illustrate operation of the sense amplifier 106 in the memory 100 when reading from memory cells 112 in the top bank 102. As will be apparent but not discussed in detail, memory cells in the bottom bank 104 are read when the switches in the sense amplifiers 106 are suitably configured to couple the circuitry in the sense amplifiers 106 to the bit lines in the bottom bank instead of the bit lines of the top bank. In particular, FIG. 3 illustrates operation when an enabled memory cell 112 couples together the corresponding bit lines BL, BL′ together (e.g., storing a logical “0”), whereas FIG. 4 illustrates operation when an enabled memory cell 112 does not couple together the corresponding bit lines BL, BL′ (e.g., storing a logical “1”).

Operation of the memory 100 has three exemplary states: idle, transition, and evaluation.

Referring to FIG. 3, during idle state 302, the bit lines BL (FIG. 1) are precharged to Von and bit lines BL′ are “precharged” to ground by multiplexer 210 (FIG. 2) since switches 214 and 21$ are closed and switches 216, 220 are open. The address decoder 108 is inactive since the word lines WL are low (substantially at V_{SS} or ground), and the sense amplifier 106 is not enabled since switch 238 is open. During this time, the voltages on nodes 224 and 228 are set to substantially V_{DD} (equalized) since switches in switch group 250 are closed. Because switches 240 and 242 are closed and the signal BUMP is low (substantially at ground or V_{SS}), capacitors 232 and 234 are charged. Because, in this example, both nodes 224 and 228 are both high, the output of the sense amplifier (DATA OUT) is high impedance (undefined). It is understood that in alternative embodiments DATA OUT can be low or high by suitably reconfiguring the inverters 246 and output transistors 248. The above-described configuration of the switches in the memory 100 generally results in low power consumption while the memory is in the idle state.

Once an address is applied to the address decoder 108 and a read request signal is asserted to controller 120, the memory enters the transition state 304 during which a word line WL is driven high (to approximately V_{DD}), the bit lines BL, BL′ are released from V_{DD} and V_{SS}, respectively, the bit lines coupled to corresponding inputs 206, 206′ due to the reconfiguration of the switches in multiplexer 210. Depending on the address applied to the decoder 108 and controller 120, other multiplexers (not shown) will couple other bit lines to nodes 206, 206′ as discussed above.

During the transition state, the memory cells coupled to the enabled word line either draw together the voltages on their respective bit line pairs (i.e., the voltage on bit line BL and node 206 decreases from V_{DD} while the voltage on bit line BL′ and node 206′ concurrently increases from V_{SS}) or leave the voltages on the bit lines essentially unchanged. However and unlike switch 222, switch 226 opens to reduce capacitive loading on node 228 since in tins example data is being read from the top bank 102.

As the voltage on hit line pairs coupled to the inputs 206, 206′ changes, the voltages on corresponding nodes 224 and 228 also change. As shown in FIG. 3, the voltage on node 224 tracks the reduction in voltage on bit line BL since switches 216 and 222 are closed. However, because bit line BL′ is AC-coupled to node 228 via capacitor 232, as the voltage on BL′ rises, the voltage on node 228 is raised above V_{DD} by, for example, a few tens of millivolts in one embodiment.

After waiting a sufficient time for the enabled memory cell to change the voltages on the bit line pairs BL, BL′ by a desired amount, e.g. 100 mV, then the controller 120 opens switch 222 decouple bit line BL from the node 224 initiating the evaluation phase 306. The opening of switch 222 reduces capacitive loading on node 224 to speed-up operation of the cross-coupled amplifier 230, once enabled, during the evaluation phase.

The purpose of which will be described in more detail in connection with FIG. 4, signal BUMP transitions from low to high at approximately the same time as switch 222 is opened. Because switch 240 is closed, capacitor 234 capacitively couples the signal BUMP to node 224 and the transition in the signal BUMP injects charge into node 224, causing a “bump” 310 in the voltage on node 224.

After waiting a short delay after the beginning of the evaluation state to allow for the charge injection by the BUMP signal to take effect, the controller 120 closes switch 238 to enable the cross-coupled amplifier 230. Because of the difference in voltage between nodes 224 and 228, the cross-coupled amplifier 230 regeneratively amplifies this voltage difference to quickly resolve what the logic value is stored in the enabled memory cell (a logical “0” in this instance) and DATA OUT goes low.

The timing relationship between the transition in the signal BUMP, closing of switch 238, and opening of switch 222 is exemplar and might be different, depending on requirements of the memory 100, the integrated circuit manufacturing process used to fabricate the memory, operating voltage and temperature, etc.

In contrast to the exemplary operation shown in FIG. 3, if the enabled memory cell does not change the voltages on the respective bit lines, then the effect of the BUMP signal on the cross-coupled amplifier 230 is different from that shown in FIG. 3. Turning to FIG. 4, operation of the memory 100 is illustrated for the case where the enabled memory cell 112 does not significantly affect the voltages of the corresponding bit line pair BL, BL′. Here, the operation and timing of the switches is the same as described in connection with FIG. 3 and the idle state 402 is essentially the same as the idle state 302. However, in the transition state 404, the voltages on nodes 224 and 228 do not change appreciably in contrast to that shown in transition state 304. During the evaluation state 406, the transition in the signal RUMP injects charge into node 224, causing the voltage “bump” 410 on node 224 of, in one exemplary embodiment, a few tens of millivolts. Then the cross-coupled amplifier 230 is enabled by the closure of switch 23$ and the amplifier 230 rapidly discharges node 228 to V_{SS} and the voltage on node 224 is returned to V_{DD}. Then the cross-coupled amplifier 230 regeneratively amplifies this voltage difference to quickly resolve what the logic value is stored in the enabled memory cell (a logical “1” in this instance) and DATA OUT goes high.

The “bump” in the voltage on node 224 serves to unbalance the amplifier 230 to allow the amplifier to quickly converge when no significant change in the bit line voltages occurs or to overcome any offset voltage, intentional (e.g., by using different device sizes) or unintentional (e.g., due to manufacturing variations), the amplifier 230 might have. The amount of capacitance for capacitor 234 (and capacitor 232) is chosen to be sufficient for injecting, enough charge so that the concomitant voltage “bump” 410 is sufficient for the amplifier 230 to rapidly converge but not so much that the amount of voltage “bump” 310 is sufficient to cause the cross-coupled amplifier 230 to operate incorrectly and produce the wrong output data (e.g., a logical “1” instead of a logical “0”) over all expected processing, voltage, and temperature parameter limits of the memory 100.

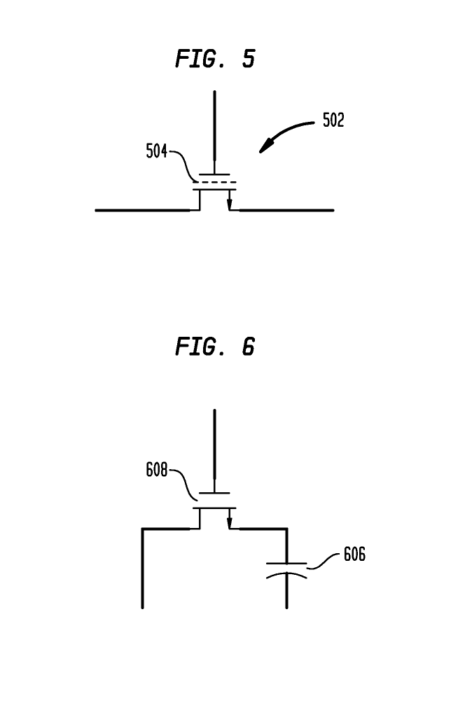

FIGS. 5 and 6 illustrates alternative memory cell embodiments other than a ROM cells 112 shown in FIG. 1. In FIG. 5, a non-volatile memory cell is illustrated having a conventional floating gate transistor 502, acting as an access transistor, where the amount of charge on the floating gate 504 represents the logic value stored in the cell. FIG. 6 illustrates a conventional dynamic memory (volatile) cell that utilizes an access transistor 608 and a storage capacitor 606 that holds a charge representing the logic value stored in the cell.

While embodiments have been described with respect to circuit functions, the embodiments of the present invention are not so limited. Possible implementations, either as a stand-alone memory or as memory embedded with other circuit functions, may be embodied in or part of a single integrated circuit, a multi-chip module, a single card, system-on-a-chip, or a multi-card circuit pack, etc. but are not limited thereto. As would be apparent to one skilled in the art, the various embodiments might also be implemented as part of a larger system. Such embodiments might be employed in conjunction with, for example, a digital signal processor, microcontroller, field-programmable gate allay, application-specific integrated circuit, or general-purpose computer. It is understood that embodiments of the invention are not limited to the described embodiments, and that various other embodiments within the scope of the following claims will be apparent to those skilled in the art.

1. In a memory having at least one sense amplifier, the at least one sense amplifier comprising:
a cross-coupled gain stage having first and second amplifier nodes;
a first switch selectively coupling the first amplifier node to a first input of the sense amplifier;
a second switch selectively coupling a first internal node to a second input of the sense amplifier;
first capacitor coupled between the first internal node and the second amplifier node; and
a second capacitor coupled between the first amplifier node and a second internal node;
wherein the first and second switches operate in response to a first control signal.

2. The memory of claim 1 further comprising:
a first precharge switch selectively coupling the first input of the sense amplifier to a power supply node; and
a second precharge switch selectively coupling the second input, of the sense amplifier to ground;
wherein the first and second precharge switches operate in response to a second control signal that is a logical complement to the first control signal.

3. The memory of claim 1 wherein the cross-coupled amplifier comprises:
a first pair of transistors having gate terminals connected to the first amplifier node and having output terminals serially coupled between a power supply node, the second amplifier node, and a switch node;
a second pair of transistors having gate terminals connected to the second amplifier node and having output terminals serially coupled between the power supply node, the first amplifier node, and the switch node; and
a switch selectively coupling the switch node to ground in response to an enable signal.

4. The memory of claim 3 further comprising precharge transistors selectively coupling the first and second amplifier nodes to a power supply node.

5. The memory of claim 1 further comprising:
a first bit line in a memory array connected to the first input of the sense amplifier; and
a second hit line in the memory array connected to the second input of the sense amplifier;
wherein the first bit line and the second bit lines are complementary.

6. The memory of claim 5 further comprising at least one memory cell having an access transistor with a control terminal and first and second output terminals, the first output terminal connected to the first bit line and the second output terminal that may connect to the second bit line depending on data stored in the memory cell.

7. The memory of claim 5 further comprising at least one memory cell having an floating gate access transistor with a control terminal and first and second output terminals, the first output terminal connected to the first hit line and the second output terminal connected to the second bit line.

8. The memory of claim 5 further comprising at least one memory cell having:
an access transistor with a control terminal and first and second output terminals, the first output terminal connected to the first bit line; and
a capacitor connected between the second output terminal and the second bit line.

9. The memory of claim 1 further comprising:
a third switch selectively coupling a control node to the second internal node;
a fourth switch selectively coupling the second internal node to a third input of the sense amplifier:
a fifth switch selectively coupling the second amplifier node to a fourth input of the sense amplifier; and
a sixth switch selectively coupling the first internal node to the control node;
wherein the fourth and fifth switches operate in response to a second control signal.

10. The memory of claim 9 further comprising:
a first bit line in a memory array connected to the first input of the sense amplifier; and
a second bit line in the memory array connected to the second input of the sense amplifier;
a third bit line in a memory array connected to the third input of the sense amplifier; and
a fourth bit line in the memory array connected to the fourth input of the sense amplifier;
wherein the first bit line and the second bit lines are configured to carry complementary data and the third and fourth bit lines are configured to carry complementary data.

11. The memory of claim 9 further comprising:
a first precharge switch selectively coupling the first input of the sense amplifier to a power supply node;
a second precharge switch selectively coupling the second input of the sense amplifier to ground;
a third precharge switch selectively coupling the third input of the sense amplifier to ground; and
a fourth precharge switch selectively coupling the fourth input of the sense amplifier to the power supply node;
wherein the first and second precharge switches operate in response to a control signal that is a logical complement to the first control signal and the third and fourth precharge switches operate in response to a control signal that is a logical complement to the second control signal.

12. The memory of claim 11 wherein:
the first switch, the fifth switch, the first precharge switch, and the fourth precharge switch are each a transistor of a first conductivity type,
the second switch, the fourth switch, the second precharge switch, and the third precharge switch are each a transistor of a second conductivity type different from the first conductivity type, and
the third switch and the sixth switch are each a pass gate.

13. The memory of claim 1 wherein when the memory is not being read., then the sense amplifier is configured so that the first and second switches are open, the cross-coupled amplifier is not enabled, and the second internal node is driven by a signal having a voltage approximately that of ground; and when the Memory is being read, then the sense amplifier is configured so that the cross-coupled amplifier is enabled after the first and second switches are closed, and the second internal node is driven by a signal having a voltage approximately that of a power supply node after the first and second switches are closed and before the cross-coupled amplifier is enabled.

14. The memory of claim 13 further comprising a switch adapted to selectively decouple the first amplifier node from the first switch before the second internal node is driven to the voltage of the power supply node.

15. The memory of claim 13 further comprising a controller configured to control operation of the first switch, the second switch, the cross-coupled amplifier, and the voltages applied to the second internal node.

16. The memory of claim 1 wherein the memory is formed in an integrated circuit.

17. In an integrated circuit, a memory having at least one sense amplifier, the at least one sense amplifier comprising:
a first pair of transistors having gate terminals connected to a first amplifier node and having, output terminals serially coupled between a power supply node, a second amplifier node, and a switch node;
a second pair of transistors having gate terminals connected to the second amplifier node and having output terminals serially coupled between the power supply node, the first amplifier node, and the switch node;
a first switch selectively coupling the first amplifier node to a first input of the sense amplifier;
a second switch selectively coupling a first internal node to a second input of the sense amplifier;
first capacitor coupled between the first internal node and the second amplifier node;
a second capacitor coupled between the first amplifier node and a second internal node;
a third switch selectively coupling a control node to the second internal node;
a fourth switch selectively coupling the second internal node to a third input of the sense amplifier;
a fifth switch selectively coupling the second amplifier node to a fourth input of the sense amplifier;
a sixth switch selectively coupling the first internal node to the control node:
a first precharge switch selectively coupling the first input of the sense amplifier to a power supply node:
a second precharge switch selectively coupling the second input of the sense amplifier to ground;
a third precharge switch selectively coupling, the third input of the sense amplifier to ground; and
a fourth precharge switch selectively coupling the fourth input of the sense amplifier to the power supply node;
wherein the first and second switches operate in response to a first control signal, the fourth and fifth switches operate in response to a second control signal, the first and second precharge switches operate in response to a control signal that is a logical complement to the first control signal, and the third and fourth precharge switches operate in response to a control signal that is in logical complement to the second control signal.

18. A method of reading data from a memory having at least one pair of bit lines, comprising the steps of:
precharging a first one of the pair of bit lines to a first voltage;
precharging a second one of the pair of bit lines to a second voltage different from the first voltage;
DC-coupling the first one of the pair of bit lines to a first input of a cross-coupled amplifier;
AC-coupling the second one of the pair of bit lines to a second input of the cross-coupled amplifier;
enabling a memory cell coupled between the first and second one of the pair of bit lines;
injecting a charge of current into the first input of the cross-coupled amplifier; and then
enabling the cross-coupled amplifier.

19. The method of claim 18 wherein the step of injecting a charge comprises the steps of:
AC-coupling the first input of the cross-coupled amplifier to a control node;
driving the control node from approximately the second voltage to approximately the first voltage before the cross-coupled amplifier is enabled.

20. The method of claim 18 further comprising the step of:
decoupling, before the step of driving the control node, the first node from the first one of the pair of bit lines.
